(19) United States
(12) Patent Application Publication
(10) Pub. No.: US 2007/0061663 A1
(43) Pub. Date: Mar. 15, 2007

(54) Method and system for identifying root cause of network protocol layer failures

(76) Inventors: Aaron J. Loyd, Fort Collins, CO (US); Srikanth Natarajan, Fort Collins, CO (US); Edwin P. Jones, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/497,387

(22) Filed: Aug. 2, 2006

Related U.S. Application Data
(60) Provisional application No. 60/707,527, filed on Aug. 12, 2005.

(51) Int. Cl. H04L 1/00; H03M 13/00; G08C 25/00; G06F 11/00; G06F 11/30

(52) U.S. Cl. 714/746

(57) ABSTRACT

A method and system are disclosed for analyzing an event in a network. For example, the method for analyzing an event in a network includes identifying a network protocol error in the network, identifying a network hardware failure in the network, correlating the network protocol error and the network hardware failure to determine a correlation result, and outputting the correlation result to a user interface. The correlation output can provide an indication of a relationship between the network protocol error and the network hardware failure.

### RELATED APPLICATIONS

This application claims priority under 35 U.S.C. §119 of U.S. Provisional Application No. 60/707,527 (Attorney Docket No. 200503226-1), filed Aug. 12, 2005. The entire contents of the above provisional application are hereby incorporated by reference.

### BACKGROUND

Routers implementing various protocols (e.g., OSPF, BGP, etc.) can have a number of protocol errors that can be caused by an underlying hardware failure. Routers can be considered layer 3 devices, whereas data switches are considered layer 2 devices in the Open Systems Interconnection Reference Model (OSI Model or OSI Reference Model for short). Routers can generate SNMP traps when protocol errors occur in a network. Routers can also generate syslog entries for protocol errors. Management servers can be deployed in a network to serve as protocol listeners and detect protocol errors in the network. These protocol listeners can generate SNMP traps when protocol errors or events occur in a network.

The ability to determine the root cause of a network protocol error can affect the speed of diagnosis and repair of a network problem. For example, the underlying failure event can be a network hardware failure, e.g., an interface failure, a node failure, and/or a connection failure. The hardware failure can be in at least one of layers 2 and 3 of OSI Model. For these exemplary hardware failures, and other related hardware failures, the ability to correlate a protocol event and a hardware failure can impact the mean time to repair a network problem. The actual cause of a protocol error is not readily apparent to a user, such as a network administrator.

### SUMMARY

A method and system are disclosed for analyzing an event in a network. For example, a method for analyzing an event in a network includes identifying a network protocol error in the network, identifying a network hardware failure in the network, correlating the network protocol error and the network hardware failure to determine a correlation result, and outputting the correlation result to a user interface to provide an indication of any relationship between the network protocol error and the network hardware failure.

A system is also disclosed for analyzing an event in a network. The system includes at least one of a router and a protocol listener configured in a network to generate data associated with a protocol event, and a server for processing the data. The server can include a user interface, a memory configured to store at least one of syslogs and network topology, and a processor coupled to the memory. The processor can include logic configured to identify a network hardware failure in the network; and logic configured to correlate the data associated with a protocol event and the network hardware failure to determine a correlation result for output to the user interface. The correlation result can provide an indication of any relationship between the protocol event and the network hardware failure.

An apparatus is disclosed for analyzing an event in a network. The apparatus includes means for receiving data associated with a protocol event; means for identifying a network hardware failure; means for correlating the data associated with a protocol event and the network hardware failure to determine a correlation result; and means for outputting the correlation result to a user interface to provide an indication of any relationship between the protocol event and the network hardware failure.

A computer readable medium containing a computer program is disclosed for analyzing an event in a network. The computer program contains steps for causing a computer to identify a network protocol error in the network, identify a network hardware failure in the network, correlate the network protocol error and the network hardware failure to determine a correlation result, and output the correlation result to a user interface to provide an indication of any relationship between the network protocol error and the network hardware failure.

### BRIEF DESCRIPTION OF THE DRAWING FIGURES

The figures illustrate exemplary systems and methods, wherein:

FIG. 1 depicts an exemplary system for analyzing an event in a network;

FIG. 2 depicts a process flow diagram for correlating protocol error and hardware failure;

FIG. 3 depicts exemplary steps for correlating traps to determine a failure event;

FIG. 4 shows exemplary steps for determining whether a protocol event is correlated with a hardware failure of a router;

FIG. 5 shows exemplary steps for determining whether a protocol event is correlated with at least one network address based on a network prefix;

FIG. 6 shows exemplary steps for determining whether a protocol event is correlated with a layer 3 router failure; and

FIG. 7 shows exemplary steps for determining whether a protocol event is correlated with a layer 2 switch failure.

### DETAILED DESCRIPTION

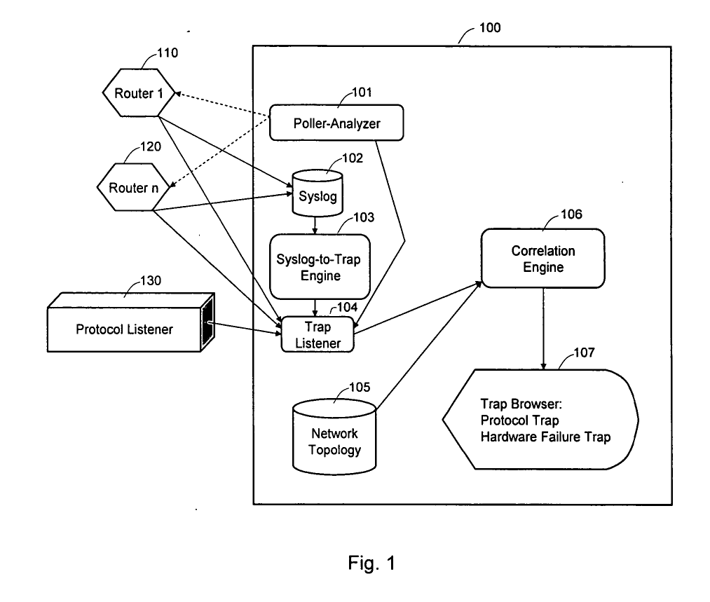

As shown in FIG. 1, an exemplary system for analyzing an event in a network can include at least one of routers 110, 120 and protocol listeners 130 configured in a network to generate data, such as at least one of traps and syslog entries associated with a protocol event. Data switches and other layer 2 network devices can also be connected in the network. A receiving means, such as a server 100, is networked to receive and process traps and syslog entries from the likes of routers 110, 120 and protocol listeners 130. The server 100 can include a user interface 107, at least one memory (e.g., database for syslog 102, database for network topology 105) configured to store data, such as at least one of syslogs and network topology, and a processor (not shown) coupled to the memory.

The server 100 can be an apparatus for analyzing an event in a network which includes hardware or software modules, which can be configured to perform different functions. For example, the server can be configured to include means, such as software and/or hardware modules 102, 104 configured as a syslog device and a trap listener, respectively, for receiving at least one of traps and syslog entries, associated with a protocol event 102, 104; means, such as software or hardware module 101 for identifying a network hardware failure in the network; means, such as a software and/or hardware module 106 configured as a correlation engine, for correlating the traps associated with a protocol event and the network hardware failure to determine a correlation result; and means, such as a software and/or hardware module 107, for outputting the correlation result to a user interface of the module 107 to provide an indication of any relationship between the protocol event and the network hardware failure. Where the data includes a trap and/or a syslog entry, the server can be configured to include means for converting syslog entries associated with a protocol event into traps associated with a protocol event 103.

The various means can be configured as, e.g., software, firmware or any other processing capability to implement a method for analyzing an event in a network. For example, means or logic can be configured to perform conversion of the syslog entries associated with a protocol event into traps associated with a protocol event via a syslog-to-trap engine 103, identification of a network hardware failure in the network (e.g., via a polling/analysis module 101), and correlation of the traps associated with a protocol event and the identification of network hardware failure in correlation engine 106 to determine a correlation result for output to the user interface. The correlation result can provide an indication of relationship between the protocol event and the network hardware failure, if any. The means or logic for identifying a network hardware failure in the network can be implemented as the poller-analyzer 101 (i.e., polling/analysis module) comprising various logic configured to poll and detect a network hardware failure (e.g., in a router 110, 120) and generate at least one (SNMP) trap to identify a network hardware failure in various layers (e.g., layer 2 and layer 3) of networked devices.

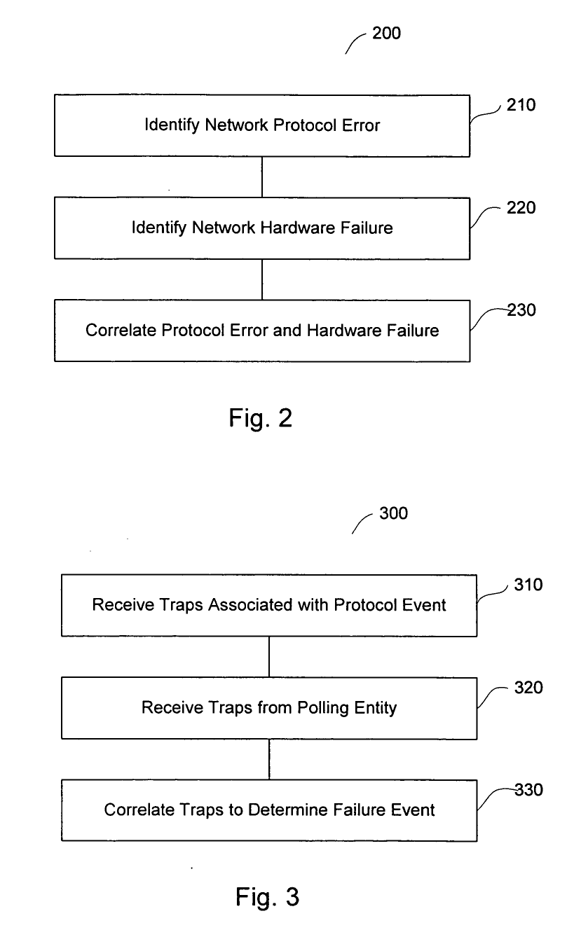

Various means can be configured as, e.g., software, firmware or any other processing capability to implement a method for analyzing an event in a network as shown in FIG. 2. For example, various means or logic can implement steps of a method, including identifying a network protocol error in the network as shown in block 210; identifying a network hardware failure in the network as shown in block 220; and correlating the identification of network protocol error and the identification of network hardware failure to determine a correlation result for output to the user interface as shown in block 230.

By way of example, referring to FIG. 1, a software process can listen via trap listener 104 for SNMP traps and syslog entries(see, 120) from routers 110, 120 and/or protocol listener 130 which define a protocol event. The server 100 correlates these traps defining a protocol event with the traps sent by the poller-analyzer 101 by way of a correlation engine 106. Whether characterized as configurable logic or as a method, the results of such a correlation can be displayed in a trap browser of user interface 107. A protocol trap can be graphical arranged as a parent display entity, and a correlated hardware failure trap can be visually arranged as a child display entity, the parent/child display relationship being visually sequenced, layered and/or linked for interactive control of display. Other like configurations, combinations of configurations or variations in the configurations for analyzing an event in a network are all considered within the scope of the present disclosure.

FIGS. 3-7 illustrate functions which can be implemented by the processor represented generally as server 100 in FIG. 1. Referring to FIG. 3, additional logic can be configured to receive traps associated with a protocol event as shown in block 310, and receive at least one trap associated with a network hardware failure as shown in block 320. Further logic can be configured to correlate the traps associated with a protocol event with the at least one trap associated with a network hardware failure to determine a correlation result for output to the user interface as shown in block 330.

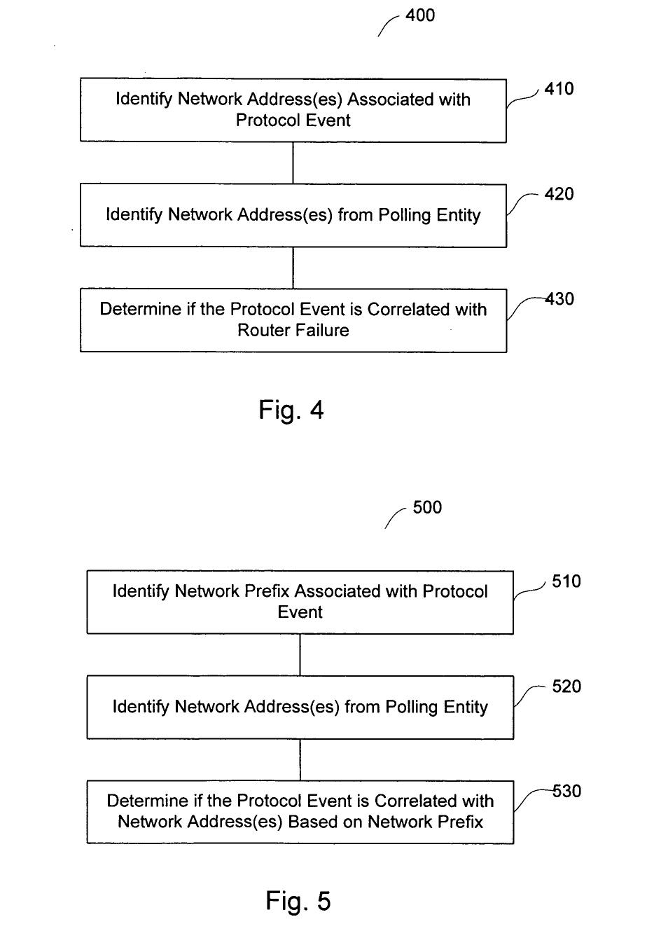

Referring to FIG. 4, various means can be configured as, e.g., software, firmware or any other processing capability to implement a method for analyzing an event in a network to determine that a protocol event is correlated with a hardware failure of a router as shown in FIG. 4. For example, means, including configurable logic, can implement a step as shown in block 410 to identify at least one network address associated with a protocol event. Means, such as logic, can be configured as shown in block 420 to identify at least one network address associated with a network hardware failure. Means, such as logic, can be configured as shown in block 430 to determine that the protocol event is correlated with a hardware failure of a router based on matching the at least one network address associated with a protocol event with the at least one network address associated with a network hardware failure.

Referring to FIG. 5, various means can be configured as, e.g., software, firmware or any other processing capability to implement a method for analyzing an event in a network to determine that a protocol event is correlated with at least one network address associated with a network hardware failure as shown in FIG. 5. For example, means, including configurable logic, can implement a step as shown in block 510 to identify a network prefix associated with a protocol event. Means, such as logic, can be configured as shown in block 520 to identify at least one network address associated with a network hardware failure. Means, such as logic, can be configured as shown in block 530 to determine that the protocol event is correlated with the at least one network address associated with a network hardware failure based on matching the network prefix associated with a protocol event with a prefix of the at least one network address associated with a network hardware failure.

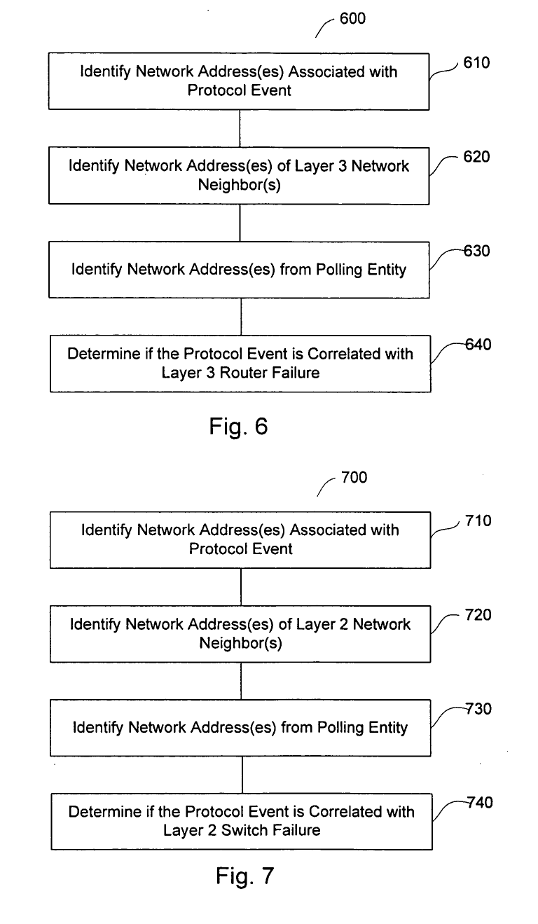

Referring to FIG. 6, means, such as logic, can be configured as, e.g., software, firmware or any other processing capability to implement a method for analyzing an event in a network to determine that a failure in a layer 3 router (e.g., a BGP router) associated with a protocol event caused an identification of a network address of at least one layer 3 network neighbor. For example, means, including configurable logic, can implement a step shown in block 610 to identify at least one network address associated with a protocol event. Means, such as logic, can be configured as shown in FIG. 620 to identify a network address of at least one layer 3 network neighbor of the at least one network address associated with a protocol event based on the stored network topology 105. Means, such as logic, can be configured as shown in FIG. 630 to identify at least one network address associated with a network hardware failure. Means, such as logic, can be configured as shown in FIG. 640 to determine that a failure in a layer 3 router associated with the protocol event caused the identification of a network address of at least one layer 3 network neighbor based on matching the network address of at least one layer 3 network neighbor of the at least one network address associated with a protocol event with the at least one network address associated with a network hardware failure.

Referring to FIG. 7, various means can be configured as, e.g., software, firmware or any other processing capability to implement a method for analyzing an event in a network to determine that a failure in a layer 2 switch associated with a protocol event (e.g., an OSPF/ISIS protocol event) caused an identification of a network address of at least one layer 2 network neighbor. For example, means, including configurable logic, can implement a step as shown in block 710 to identify at least one network address associated with a protocol event. Means, such as logic, can be configured as shown in block 720 to identify a network address of at least one layer 2 network neighbor of the at least one network address associated with a protocol event based on the stored network topology 105. Means, such as logic, can be configured as shown in block 730 to identify at least one network address associated with a network hardware failure. Means, such as logic, can be configured as shown in block 740 to determine that a failure in a layer 2 switch associated with the protocol event caused the identification of the network address of at least one layer 2 network neighbor based on matching the network address of at least one layer 2 network neighbor of the at least one network address associated with a protocol event with at least one network address associated with a network hardware failure.

An exemplary correlation algorithm (e.g., correlation engine 108) is set forth below as a pseudo-code description.

The following pseudo-code description is intended to be exemplary, but not limiting.

```
For each RAMS event in RAMS event array
Do
  Var addr1 = RAMS event source address
  Var mask1 = RAMS event source mask
  Var addr2 = RAMS event destination address
  For each APA event in APA event array
  Do
  Var apaAddr1 = APA event source address
  Var apaAddr2 = APA event destination address
  Var apaSrcNodeOid = APA event source node's OID
  Var apaSrcIfOid = APA event source interface's OID
  Var apaDestNodeOid = APA event destination node's OID
  Var apaDestIfOid = APA event destination interface's OID
  If (addr1 == apaAddr1) CORRELATE
  If (addr1 == apaAddr2) CORRELATE
  If (addr2 == apaAddr1) CORRELATE
  If (addr2 == apaAddr2) CORRELATE
  If (mask1 is valid)
  Do
    Var Range = addr1 combined with mask1
    If (apaAddr1 is in Range) CORRELATE
    If (apaAddr2 is in Range) CORRELATE
  Done
  Var srcNodeOid = Topology.getNodeOid(addr1)
  If (srcNodeOid == apaSrcNodeOid) CORRELATE
  Var destNodeOid = Topology.getNodeOid(addr2)
  If (destNodeOid == apaDestNodeOid) CORRELATE
  // find the interfaces that share the same subnet
  Var srcIP = null
  Var destIP = null
  Var srcIfList = Topology.getInterfaceList(addr1)
  Var destIfList = Topology.getInterfaceList(addr2)
  For each srcIf in srcIfList
  Do
    Var srcIfSubnet = Topology.getSubnet(srcIf)
    For each destIf in destIfList
    Do
        Var destIfSubnet = Topology.getSubnet(destIf)
        If (srcIfSubnet == destIfSubnet)
        Do
          Var srcIP = Topology.getInterfaceIP(srcIF)
          Var destIP = Topology.getInterfaceIP(destIf)
          Break
        done
      done
    done
  if (srcIP == null)
  do
    srcIP = addr1
    destIP = addr2
  done
  Var nsList = Topology.getNeighbors(srcIP)
  For each neighbor in nsList
  Do
    If (neighbor.node.Oid == apaSrcNodeOid) CORRELATE
    If (neighbor.interface.Oid == apaSrcIfOid) CORRELATE
    If (neighbor.node.Oid == apaDestNodeOid) CORRELATE
    IF (neighbor.interface.Oid == apaDestIfOid) CORRELATE
  Done
  Var ndList = Topology.getNeighbors(destIP)
  For each neighbor in ndList
  Do
    If (neighbor.node.Oid == apaSrcNodeOid) CORRELATE
    If (neighbor.interface.Oid == apaSrcIfOid) CORRELATE
    If (neighbor.node.Oid == apaDestNodeOid) CORRELATE
    IF (neighbor.interface.Oid == apaDestIfOid) CORRELATE
  done
done
// Note that CORRELATE means correlation of two events that are being
examined, but the other events in the array(s) continue to be examined.
```

In the exemplary correlation algorithm, each node and interface stored in network topology memory 106 is given a unique Object Identifier (OID), referred to in the pseudocode as “Oid”. OIDs can be compared to determine whether the two compared addresses are of the same node, e.g., a lookup of two IP addresses may return the same OID value. The source code is outlined as follows:
1. If the source address of a protocol (e.g., protocol listener) event matches a source address of an active poller-analyzer (APA) event, then the two addresses correlated.
2. If the source address of the protocol (e.g., protocol listener) event matches the destination address of the APA event, then the two addresses correlate.
3. If the destination address of the protocol (e.g., protocol listener) event matches the source address of the APA event, then the two addresses correlate.
4. If the destination address of the protocol (e.g., protocol listener) event matches the destination address of the APA event, then the two addresses correlate.
5. If a subnet mask was provided (in the case of prefix events), apply the subnet mask to the network address provided in the source address. If the source address or the destination address of the APA event falls within the range of addresses (network address plus mask) then correlate.
6. If both source and destination protocol addresses were provided (e.g., by protocol listener), then access ET topology and step through the interfaces on the source and destination to find a pair of interfaces sharing the same subnet. If a pair of interfaces sharing the same subnet is found, then the IP addresses of the pair of interfaces are used in the following, else the original source and destination IP addresses (e.g., by protocol listener) are used in the following. If only a source address is provided (e.g., by protocol listener), then only the source address (e.g., by protocol listener) is used in the following:
   a. Get the ET OID of the source node (e.g., by protocol listener). Compare source OID to the ET OID of the APA source node. If they match, then they correlate. Compare source OID to the ET OID of the APA destination node, if they match, then they correlate.
   b. Find the level 2 (L2) neighbors of the source node (e.g., by protocol listener). If a L2 neighbor OID matches the APA source node OID or the APA destination node OID, then they correlate.
   c. Get the L2 interface on the neighbor node. If the neighbor interface OID matches the APA source interface OID or the APA destination interface OID, then they correlate.
   d. Repeat the above three steps (a-c) for the destination node if provided (e.g., by protocol listener).
      As set forth, interfaces on the same subnet (6) are checked. A router can have a plurality interfaces and L2 neighbors. In the case of protocol events (e.g., reported by a route analytics management system (RAMS)) which have both a source and a destination, interfaces used to connect the source and destination are determined, and then L2 neighbors of those determined interfaces can be checked. If no such interface is determined, then all neighbors of the router can be determined. Each of the neighbors is then matched against the APA event to see if the APA event was generated for a neighbor device of the RAMS source or destination.

At the correlation engine 106, when an APA event is received, the event can be queued and correlated to queued protocol (RAMS) events. When a RAMS event is received we can attempt to correlate that event to the any queued APA event. If correlation succeeds, then the events correlate, else the RAMS event can be queued. This ensures that if multiple RAMS events occur, then they are all correlated to the APA event that caused the multiple protocol events. This also ensures that if the RAMS event is received before the APA event, then they can be correlated later when the APA event arrives.

The queues can be time constrained, the time window being configurable. Thus, when the window expires, all queued events can be cleared. Under this queuing scheme, a one to many comparison is possible. The code will either be comparing one RAMS event to one or more APA events or vice versa. However, the pseudo-code can handle the case of many-to-many comparisons. For RAMS and APA events, there can be at least one of source and destination information. The pseudo code can check if the destination information is null to skip destination checks.

For the case where the RAMS event only identifies a protocol problem related to a network prefix; check if the APA event addresses fall within the prefix. A prefix consists of an IP address and a mask. By combining the address with the mask, a range of IP addresses can be obtained, e.g. 15.2.122.0 to 15.2.122.127. If the APA event addresses fall within the range, then the APA event can be determined to apply to the RAMS prefix event.

Various aspects were set forth in connection with exemplary embodiments, including certain aspects described in terms of sequences of actions that can be performed by elements of a computer system. It will be recognized that various actions can be performed for each of the embodiments by specialized circuits or circuitry (e.g., discrete and/or integrated logic gates interconnected to perform a specialized function), by program instructions being executed by one or more processors, or by a combination of both. Any such form of embodiment can be referred to here as “logic configured to” perform, or “logic that” performs a described action. For example, the foregoing means or configurable logics, which variously implement a method for analyzing an event in a network, can be implemented as executable instructions of a computer program for analyzing an event in a network.

The executable instructions of a computer program for analyzing an event in a network can be embodied in any computer readable medium for use by or in connection with an instruction execution system, apparatus, or device, such as a computer based system, processor containing system, or other system that can fetch the instructions from the instruction execution system, apparatus, or device and execute the instructions. For example, a computer readable medium can contain a computer program for analyzing an event in a network implementing steps as exemplified in FIG. 2 for causing a computer to identify a network protocol error in the network (block 210), identify a network hardware failure in the network (block 220), and correlate the network protocol error and the network hardware failure to determine a correlation result (block 230). The correlation result can be output to a wide variety of user interfaces, e.g., a monitor, workstation, pc, laptop, PDA, LCD/LED screen, etc., to provide an indication of any relationship between the network protocol error and the network hardware failure.

As used here, a “computer readable medium” can be any means that can contain, store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium. More specific examples (a non exhaustive list) of the computer readable medium can include the following: an electrical connection having one or more wires, a portable computer diskette, a random access memory (RAM), a read only memory (ROM), an erasable programmable read only memory (EPROM or Flash memory), an optical fiber, and a portable compact disc read only memory (CDROM).

It will be appreciated by those of ordinary skill in the art that the concepts and techniques described here can be embodied in various specific forms without departing from the essential characteristics thereof. The presently disclosed embodiments are considered in all respects to be illustrative and not restrictive. The scope of the invention is indicated by the appended claims, rather than the foregoing description, and all changes that come within the meaning and range of equivalence thereof are intended to be embraced.

What is claimed is:

1. A method for analyzing an event in a network, the method comprising:
identifying a network protocol error in the network;
identifying a network hardware failure in the network;
correlating the network protocol error and the network hardware failure to determine a correlation result; and
outputting the correlation result to a user interface to provide an indication of any relationship between the network protocol error and the network hardware failure.

2. The method of claim 1, wherein the identifying of a network protocol error comprises:
generating at least one of an SNMP trap and a syslog entry when a network protocol error occurs; and
converting the syslog entry to an SNMP trap.

3. The method of claim 1, wherein the identifying of a network hardware failure comprises:
polling to detect a network hardware failure; and
generating at least one SNMP trap from a polling entity to identify a network hardware failure.

4. The method of claim 3, wherein the correlating comprises:
receiving the SNMP traps associated with a protocol event;
receiving the SNMP trap from a polling entity; and
correlating the SNMP traps associated with a protocol event with the at least one SNMP trap from the polling entity to determine the relationship.

5. The method of claim 1, wherein the correlating comprises:
identifying at least one network address associated with a protocol event;
identifying at least one network address from a polling entity; and
if at least one network address associated with a protocol event matches at least one network address from a polling entity, then the protocol event is determined to be correlated with a hardware failure of a router.

6. The method of claim 1, wherein the correlating comprises:
identifying a network prefix associated with a protocol event;
identifying at least one network address from a polling entity; and
if the network prefix associated with a protocol event matches a prefix of at least one network address from a polling entity, then the protocol event is determined to be correlated with the at least one network address from a polling entity having a matching prefix.

7. The method of claim 1, wherein the correlating comprises:
identifying at least one network address associated with a protocol event;
identifying a network address of at least one layer 3 network neighbor of the at least one network address associated with a protocol event;
identifying at least one network address from a polling entity; and
if the network address of at least one layer 3 network neighbor of the at least one network address associated with a protocol event matches at least one network address from a polling entity, then the protocol event is determined to be correlated with a failure in a layer 3 router, wherein the layer 3 router is a BGP router.

8. The method of claim 1, wherein the correlating comprises:
identifying at least one network address associated with a protocol event;
identifying a network address of at least one layer 2 network neighbor of the at least one network address associated with a protocol event;
identifying at least one network address from a polling entity; and
if the network address of at least one layer 2 network neighbor of the at least one network address associated with a protocol event matches at least one network address from a polling entity, then the protocol event is determined to be correlated with a failure in a layer 2 switch, wherein the protocol event is an OSPF/ISIS protocol event.

9. The method of claim 1, wherein the relationship is that the network hardware failure caused the network protocol error.

10. The method of claim 1, wherein the relationship is that at least one of an interface failure, a node failure, and a connection failure caused the network protocol error.

11. The method of claim 1, wherein the relationship is that a hardware failure in at least one of layers 2 and 3 of OSI reference model caused the network protocol error.

12. A system for analyzing an event in a network, the system comprising:
at least one of a router and a protocol listener configured in a network to generate data associated with a protocol event; and
a server for processing the data, the server including a user interface, a memory configured to store at least one of syslogs and network topology, and a processor coupled to the memory, the processor including:
logic configured to identify a network hardware failure in the network; and
logic configured to correlate the data associated with a protocol event and the network hardware failure to determine a correlation result for output to the user interface, wherein the correlation result provides an indication of any relationship between the protocol event and the network hardware failure.

13. The system of claim 12, the logic configured to identify a network hardware failure in the network comprising:
logic configured to poll and detect a network hardware failure; and
logic configured to generate at least one trap to identify the network hardware failure.

14. The system of claim 12, the processor comprising:
logic configured to receive at least one of traps and syslog entries as data associated with a protocol event;
logic configured to convert the syslog entries associated with a protocol event into traps associated with a protocol event;
logic configured to receive at least one trap associated with a network hardware failure; and
logic configured to correlate the traps associated with a protocol event with the at least one trap associated with a network hardware failure to determine the relationship.

15. The system of claim 12, the processor comprising:
logic configured to identify at least one network address associated with a protocol event;
logic configured to identify at least one network address associated with a network hardware failure; and
logic to determine that the protocol event is correlated with a hardware failure of a router based on matching the at least one network address associated with a protocol event with the at least one network address associated with a network hardware failure.

16. The system of claim 12, the processor comprising:
logic configured to identify a network prefix associated with a protocol event;
logic configured to identify at least one network address associated with a network hardware failure; and
logic to determine that the protocol event is correlated with the at least one network address associated with a network hardware failure based on matching the network prefix associated with a protocol event with a prefix of the at least one network address associated with a network hardware failure.

17. The system of claim 12, the processor comprising:
logic configured to identify at least one network address associated with a protocol event;
logic configured to identify a network address of at least one layer 3 network neighbor of the at least one network address associated with a protocol event;
logic configured to identify at least one network address associated with a network hardware failure; and
logic to determine that a failure in a layer 3 router associated with the protocol event caused the identification of a network address of at least one layer 3 network neighbor based on matching the network address of at least one layer 3 network neighbor of the at least one network address associated with a protocol event with the at least one network address associated with a network hardware failure, wherein the layer 3 router is a BGP router.

18. The system of claim 12, the processor comprising:
logic to identify at least one network address associated with a protocol event;
logic to identify a network address of at least one layer 2 network neighbor of the at least one network address associated with a protocol event;
logic to identify at least one network address associated with a network hardware failure; and
logic to determine that a failure in a layer 2 switch associated with the protocol event caused the identification of the network address of at least one layer 2 network neighbor based on matching the network address of at least one layer 2 network neighbor of the at least one network address associated with a protocol event with at least one network address associated with a network hardware failure, wherein the protocol event is an OSPF/ISIS protocol event.

19. A computer readable medium containing a computer program for analyzing an event in a network, the computer program comprising instruction steps for:
identifying a network protocol error in the network;
identifying a network hardware failure in the network;
correlating the network protocol error and the network hardware failure to determine a correlation result; and
outputting the correlation result to a user interface to provide an indication of any relationship between the network protocol error and the network hardware failure.
